(19) United States
(12) Patent Application Publication
(10) Pub. No.: US 2006/0284321 A1
(43) Pub. Date: Dec. 21, 2006

(54) LED structure for flip-chip package and method thereof

(75) Inventors: Bor-Jen Wu, Linkou Township (TW); Mei-Hui Wu, Minsyong Township (TW); Chien-An Chen, Sinjhuang City (TW); Yuan-Hsiao Chang, Taipei City (TW)

Correspondence Address: BACON & THOMAS, PLLC, 625 SLATERS LANE, FOURTH FLOOR, ALEXANDRIA, VA, 22314, US

(73) Assignee: Unit Light Technology Inc., Taoyuan Hsien (TW)

(21) Appl. No.: 11/471,482

(22) Filed: Jun. 21, 2006

(30) Foreign Application Priority Data
Jun. 21, 2005 (TW) 094120605

(51) Int. Cl. H01L 23/48

(52) U.S. Cl. 257/778

(57) ABSTRACT

LED structure can be packaged by using flip-chip package. An LED structure is covered by a conduction enhancing layer. A bumping area definition layer is then formed on the conduction enhancing layer to expose bumping area portions with p-pad and n-pad underneath, and a bumping pad is then formed over the bumping area portions. The bumping area definition layer and then exposed conduction enhancing layer is removed subsequently.

### BACKGROUND OF THE INVENTION

1. Field of the Invention

This invention relates generally to an LED structure and method of manufacturing the same, and more particularly to an LED structure for flip-chip package and method of manufacturing the same.

2. Description of the Prior Art

Concurrently, the method for packaging LED is mainly performed by wire bonding method. A schematic of wire bonding package structure for LED is shown in FIG. 1, wherein LED 20 is resided on a package substrate 10. Two conductive lines connect separately from p-contact and n-contact of LED 20 to conductive areas 12, 14 of package substrate 10. Conductive areas 12, 14 electrically connect to two leads separately, and are packaged with the whole LED 20 by epoxy resin 16.

However, such packaging method encounters several problems. First, the p-contact on LED needs a current distributing layer to increase current distributing area on LED, as shown in FIG. 2. LED 20 includes: a base 21, an active emitting layer 23 resided between an n-type conductive layer 22 and p-type conductive layer 24, an n-contact 25 and a p-contact 26 are resided on n-type conductive layer 22 and p-type conductive layer 24 separately, a current distributing layer 27 is resided on p-type conductive layer 24 to increase the current distribution on p-type conductive layer 24, and a passivation layer 28 is used for protecting LED 20. A transparent conductor is generally used for current distributing layer 27, such as: Indium Tin Oxide, Zinc Tin Oxide, or Nickel Gold Oxide. Although these materials are conductors, ohmic contacts must be formed on p-type conductive layer of LED, there are still resistors, therefore the LED generates heat when the current passing by. Besides, the transparent conductor absorbs a certain portion of light and reflect a portion of light back, and the emitting efficiency is accordingly decreasing.

Further, the LED needs a transparent passivation layer for protection, and this restricted the selection of passivation layer material. Similarly, transparent passivation layer absorbs and reflects partially, the emitting efficiency of LED is therefore decreasing.

Besides, the material used of package substrate in FIG. 1 is generally a poor thermal conductor. When the LED generates heat, the way to dissipate heat is to transmit heat from LED to conductive area 12, 14 through two thin conductive lines. This causes serious device heating problems.

Except for the aforesaid disadvantages, the height of metal line in FIG. 1 is approximately several times that of LED 20 itself, therefore the thickness of epoxy resin 16 is normally several times the height of LED 20. In considering the application, it is unlikely to provide smaller product in volume, or shorter in thickness product. Therefore, the application of LED is restricted.

In view of the aforementioned, another packaging structure is needed to overcome the above drawbacks.

### SUMMARY OF THE INVENTION

The main purpose of the present invention is to provide a LED structure for flip-chip packaging and the manufacturing method of the same. The advantages of flip-chip are that they are small in volume, thin in thickness, light in weight, and include large emitting area. Besides, the LED structure of the present invention is suitable for flip-chip package and improves the yield.

Another purpose of the present invention is to increase the contact area of LED and metal, not only for better heat dissipation effect, but also provides reflection effect.

The other purpose of the present invention is to utilize the light emitting area more efficiently.

The further purpose of the present invention is to make ohmic contact layer without the need of using transparent conductor layer for current spreading.

Another purpose of the present invention is that passivation layer is not necessarily transparent, thus the selection of materials can be less restricted.

According to the aforementioned purposes, the present invention provides a method for manufacturing LED, comprising: forming a conduction enhancing layer on a LED structure, and electrically connected to p-contact and n-contact of LED. Afterward, forming a bumping area definition layer, wherein two electrode areas are formed within bumping area definition layer. Then, forming two bumping pads on two electrode areas, and electrically connecting to conduction enhancing layer. Then, removing the bumping definition layer, and removing selectively the exposed conduction enhancing layer such that the two bumping pads are isolated electrically.

The present invention also provides a method for manufacturing LED, comprising: forming a passivation layer on a LED structure and expose p-contact and n-contact of LED. Afterward, forming a temporary layer on the passivation layer and exposing two bumping areas, wherein p-contact and n-contact are formed underneath the bumping area separately. Then, a conduction enhancing layer is formed on the temporary layer, p-contact and n-contact. Then a bumping area definition layer is formed on the conduction enhancing layer and overlapped with the temporary layer. Afterward, two bumping pads are formed on two bumping areas. Then, removing the bumping area definition layer, and removing selectively exposed conduction enhancing layer, and removing exposed conduction enhancing layer selectively.

The present provides a LED structure for flip-chip package, comprising: a substrate, and a LED structure. The LED structure is formed on the substrate, which comprising a semiconductor layer of n-type conductive semiconductor layer and a semiconductor of p-type conductor. The p-type conductive semiconductor and n-type conductive semiconductor comprise a p-contact and an n-contact separately. Besides, a passivation layer is formed on the p-type conductive semiconductor layer and the exposed n-type conductive semiconductor, and exposed p-contact and n-contact. A conduction enhancing layer is formed on p-contact and n-contact, and connected electrically to p-contact and n-contact. The two bumping pads are formed on the conduction enhancing layer, and connected electrically to p-contact and n-contact. The two bumping pads includes gold, silver, copper, nickel gold, solder bump, gold bump, silver bump, copper bump, silver epoxy or solder paste. And the substrate includes transparent material.

### BRIEF DESCRIPTION OF THE DRAWINGS

The above objects, and other features and advantages of the present invention will become more apparent after reading the following detailed description when taken in conjunction with the drawings, in which:

FIG. 1 is a schematic diagram of conventional LED packaging structure.

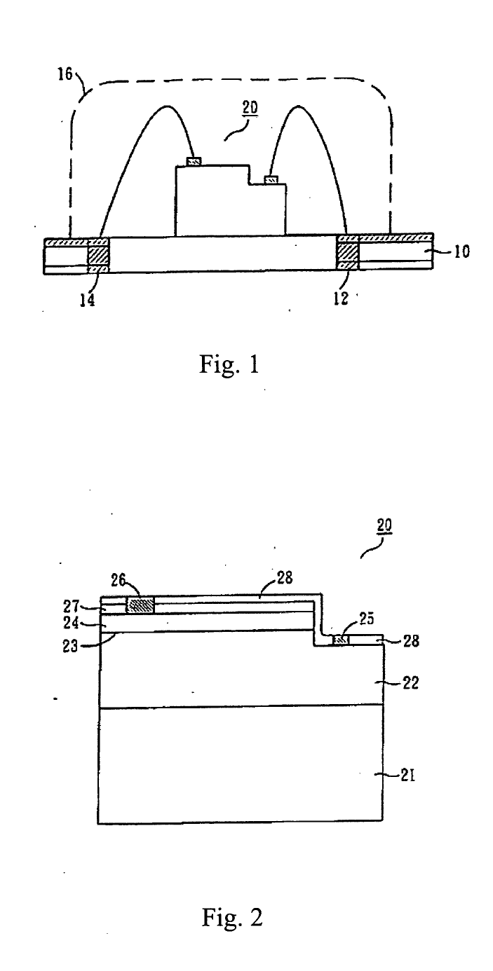

FIG. 2 is a schematic diagram of conventional LED structure.

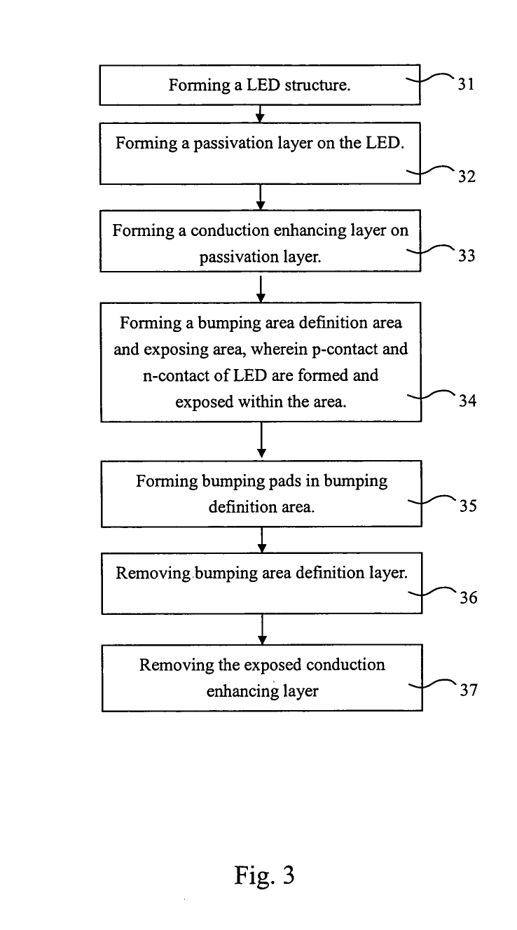

FIG. 3 is a block diagram of one embodiment of the present invention.

FIG. 4 is a block diagram of another embodiment of the present invention.

FIG. 5 is a schematic diagram of structure in each step of an embodiment of the present invention.

FIG. 6 is a schematic diagram of structure in each step of another embodiment of the present invention.

### DESCRIPTION OF THE PREFERRED EMBODIMENT

Method and structure of LED structure for flip-chip package is described below. In the following description, numerous specific details are set forth in order to provide a thorough understanding of the present invention, and the scope of the present invention is expressly not limited expect as specified in the accompanying claims.

The components of the different elements are not shown to scale. Some dimensions of the related components are exaggerated and meaningless portions are not drawn to provide clearer description and comprehension of the present invention.

The present invention is related to a method for making LEDs ready for flip-chip packaging. First, forming a conduction enhancing layer on a LED structure, and connected electrically to p-contact and n-contact of the LED structure. The LED structure is formed on a transparent substrate, and comprises a passivation layer residing on a LED structure. Afterward, forming a bumping area definition layer on a conduction enhancing layer, wherein two electrode areas are formed within bumping area definition layers. Then, forming two bumping pads on the two electrode areas, and electrically connected to conduction enhancing layer. The methods of forming bumping pads including: plating, spraying, spin coating or printing, and bumping pads can be solder bump, gold bump, silver bump, copper bump, or others such as: solder paste or silver epoxy, or metals such as: copper, gold, silver, platinum, molybdenum, titanium, nickel, palladium or their alloy. Then, the bumping area definition layer is removed, and the exposed conduction enhancing layer is removed selectively, such that electrically isolating is formed between two bump pads. The method for removing conduction enhancing layer can be etching or peeling method. The usage of peeling method needs to form an additional layer on LED structure and overlap with bumping area definition layer conduction enhancing layer before forming conduction enhancing layer.

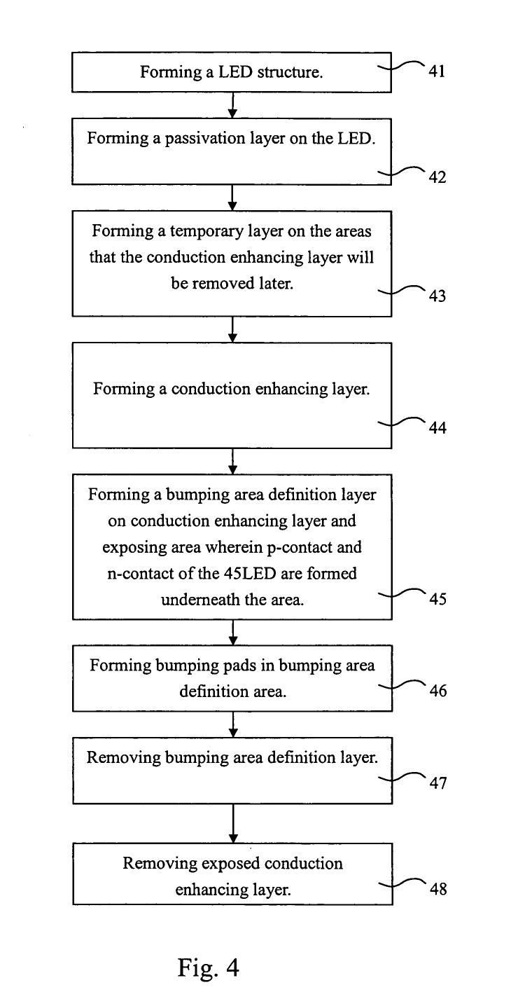

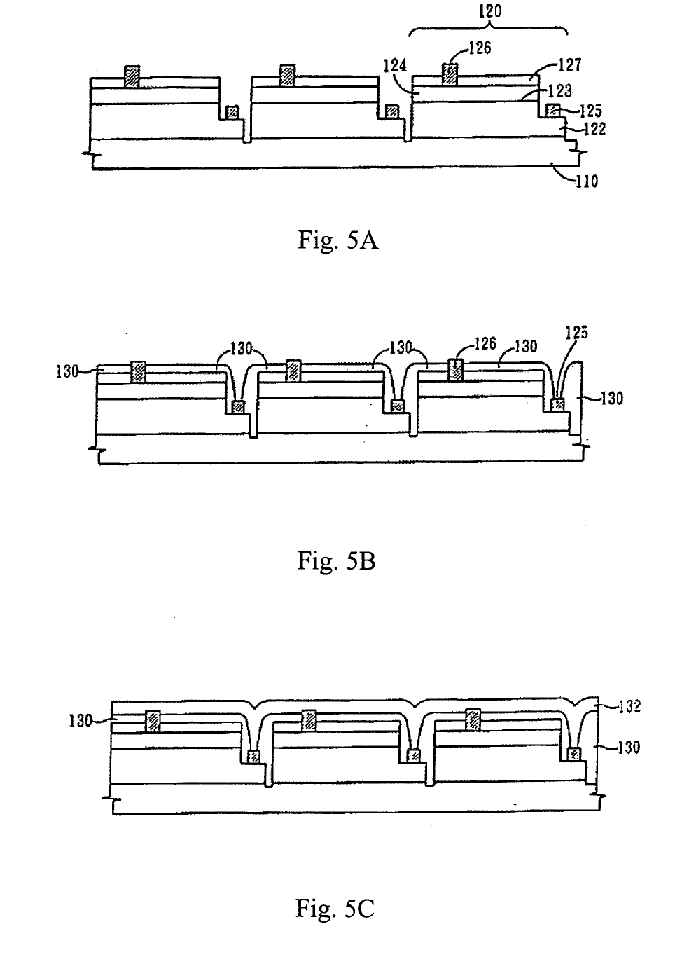

According to the feature of the present invention, the detail steps of the present invention are described in block diagram of FIG. 3, and FIG. 4. As shown in FIG. 3, A LED structure is formed in step 31. Then, in step 32, a passivation layer is formed on the LED except for p-contact and n-contact area for protecting LED structure. In the present invention, materials with better protection should be selected for passivation layer. Then, a field conduction enhancing layer is formed in step 33. The purpose of the layer is not only for enhancing the electric characteristic of p-contact and n-contact of metal bump pad and LED, when the bumping pad is formed by plating, but also be used as a metal electrode of plating. In step 34, a bumping area definition layer is formed and the area where p-contact and n-contact of LED are resided underneath are exposed. The step includes deposing bumping area definition layer and defining bumping area by photolithography. Then bumping pad is formed in definition area in step 35, wherein the step can be performed by deposition, printing or plating. Then, bumping area definition layer is removed in step 36, wherein the removing method can be used easily etching or general photolithography. Afterward, the exposed conduction enhancing layer is removed in step 37, wherein the removing method can be simple etching or photolithography.

In the last step, except for using the etching process, peeling method can also be used. To use peeling method, the prior step must be adjusted. The total steps are showed as FIG. 4.

First, LED structure is formed in step 41. Then, passivation layer is formed on LED for protecting LED structure in step 42. Afterwards, a temporary layer is formed in step 43, on which the conduction enhancing layer which must be removed in the last process. Then, a field conduction enhancing layer is formed in step 44, The purpose of this layer is not only to increase electrical characteristic between p-contact and n-contact of metal bumping pads and LED, but also to be used as a metal electrode of plating when bumping pads are formed by plating. Afterward, bumping area definition layer is formed and exposed area on conduction enhancing layer, p-contact and n-contact of LED are resided underneath the area in step 45. This step includes deposing bumping area definition layer and defining bumping area with photolithography, wherein p-contact and n-contact are underneath the bumping area. Then, bumping pads are formed on the exposed areas by means of deposition, printing or plating method in bumping area definition area in step 46. Then, the bumping area definition layer is removed in step 47, wherein the simple etching can be used for removing method. Afterward, the temporary layer is lift-off to remove exposed conduction enhancing laye in step 48.

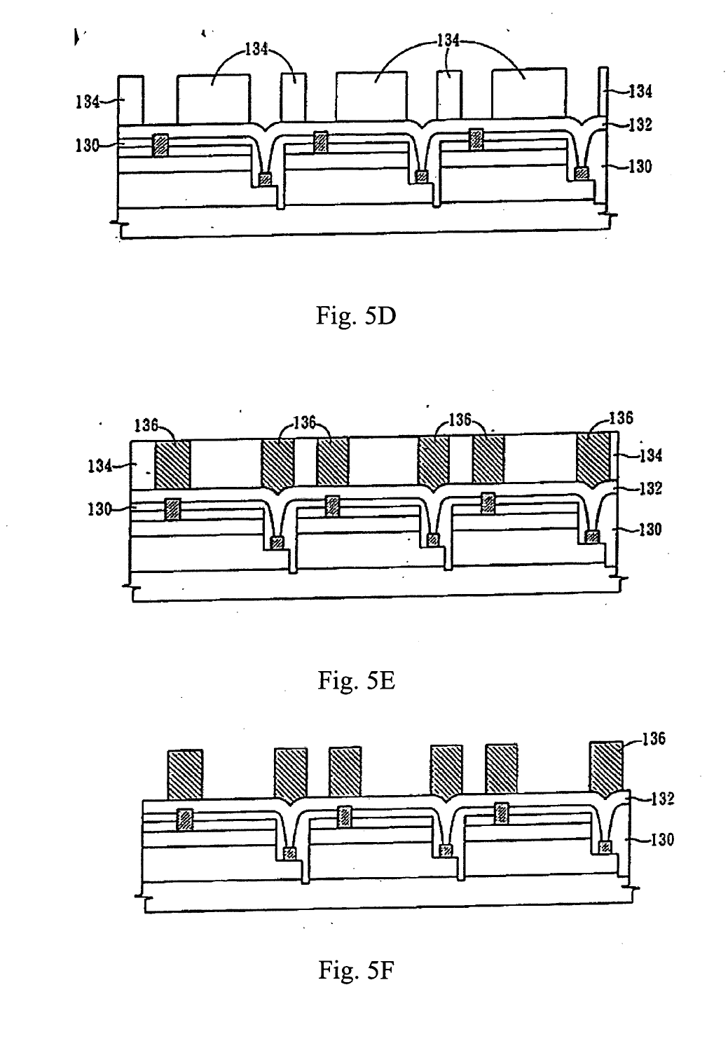

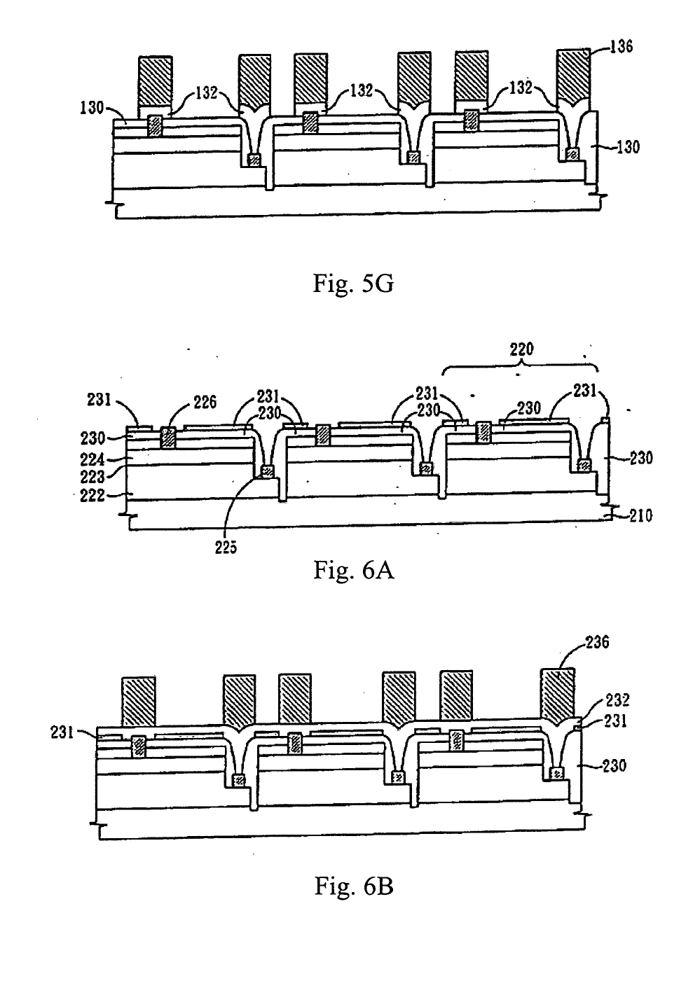

Two embodiment of the present invention are described in FIG. 5 and FIG. 6.

A LED structure 120 is formed as shown in FIG. 5A, wherein the LED structure 120 is just for example, and can be any LED in used currently. The LED 120 in the embodiment includes a transparent substrate 110, an active emitting layer 123 is resided between n-semiconductor layer 122 and p-semiconductor layer 124, and n-contact 125 on n-semiconductor layer 122, p-contact 126 on p-semiconductor 124, and current distributing layer 127 for increasing current distribution. The materials of current distribution layer 127 are usually used as the ohmic contact on p-semiconductor layer 124, and are not limited to transparent conductive materials.

As show in FIG. 5B, a passivation layer 130 is formed on LED structure 120 to protect LED structure 120, wherein the passivation layer 130 need to expose partial or all portion of p-contact and n-contact 125. The method of exposing p-contact 126 and n-contact 125 can performed by photolithography process. In the present invention, passivation layer 130 can be selected as transparent or opaque but material with better protection are favorable. In addition, the material of passivation layer 130 can be selected as non-organic material, such as: silicon oxide, aluminum oxide, silicon nitride, silicon oxide, silicon oxynitride, tantalum oxide, titanium oxide, calcium fluoride, hafnium oxide, zinc sulfide, or zinc oxide; organic materials such as: ABS resin, epoxy, PMMA, acrylonitrile butadiene styrene copolymer, polymerethylmethacrylate, polysulfones, polyethersulfone, polyetherimides, polyimide, polyamideimide, polyphenylene sulfide, or one of silicon-carbon thermosets, or the combination thereof.

As shown in FIG. 5C, a conduction enhancing layer 132 is formed on passivation layer 130 and across the whole wafer. The purpose of this layer is not only to increase the electrical characteristic between p-contact 126 and n-contact 125 of metal pads and LED 120, but also to be provided as metal pads of plating when pads are formed by plating. The material of conduction enhancing layer 132 can be selected mainly from those whom have good conductive effect with p-contact 126 and n-contact 125 of LED 120, and combined better with metal bumping. Generally, the material of conduction enhancing layer 132 can be selected as copper, gold, silver, platinum, molybdenum, titanium, nickel, palladium, or their combination of multilayer structure.

As shown in FIG. 5D, a bumping area definition layer 134 is formed wherein the contact enhancing layer on top of the p-contact 126 and n-contact 125 of LED 120 are exposed. This step includes forming bumping area definition layer 134 and defining the bumping area by photolithography. The bumping area definition layer 134 is not only provided for forming mask of bumping pads, but also be provided as support when forming bumping pads. Because the bumping area definition layer 134 will be removed after the process, the material is better selected from those materials having high selective ratio, such as: thick film photoresist, high temperature photoresist, photoresist for micromachining, ABS resin, epoxy, PMMA, acrylonitrile butadiene styrene copolymer, polymerethylmethacrylate, polysulfones, polyethersulfone, polyetherimides, polyimide, polyamideimide, polyphenylene sulfide or one of silicon-carbon thermosets, or the combination thereof.

Bumping pads 136 are formed on p-contact 126 and n-contact 125 as shown in FIG. 5E, wherein the step can be performed by method of deposition, printing or plating. Plating is preferably used. The materials such as: copper, gold, silver, platinum, molybdenum, titanium, nickel, palladium, solder bump, or copper bump, or silver epoxy, solder paste can be used for bumping pads. If the silver epoxy is selected as material of bumping pads 136, the process can be printing after baking and polishing silver paste to the structure shown in FIG. 5E.

Removing bumping area definition layer 134, the method can be done simply by photolithography or etching. When bumping area definition layer 134 is selected as high selection ration material, wet etching method can be used for removing bumping definition layer 134.

The exposed conduction enhancing layer 132 is removed as shown in FIG. 5G, wherein the removing method can be simple etching. The etching method can be wet etching or dry etching.

The peeling method can be used to removing conduction enhancing layer in another embodiment of the present invention. Similar to the last embodiment of the present invention, a LED 220 is included in FIG. 6A. The LED 220 includes a transparent substrate 210, an active emitting layer 223 is resided between n-semiconductor layer 222 and p-semiconductor layer 224, n-electrode 225 on n-semiconductor layer 222 and p-contact 226 on p-semiconductor 224, and a current distributing layer 227 for increasing current distribution. A passivation layer 230 is formed on LED structure 220 for protecting LED structure 220, wherein passivation layer 230 need to expose partial or all protion of p-contact 226 and n-contact 225 of LED 220. a temporary layer 231 is formed on the passivation layer 230. The temporary layer 231 can be photoresist material. The step includes forming temporary layer 231 and defining bumping area by photolithography, wherein p-contact 226 and n-contact 225 is resided under bumping area.

The following process is similar to the embodiment of the present invention, until the bumping pads 236 is formed as shown in FIG. 6B. Peeling method is etching a small portion around the temporary layer and in a depth approximately contact to the temporary layer. And etching temporary layer selectively with high selective ratio etching solution. In the present invention, etching a small portion in the neighborhood of where the conduction enhancing layer 232 is closed to bumping pads 236, the etching depth is where the temporary layer 231 is to be contacted. Then immersing the whole structure in photoresist-removing solution or etching solution with high selective character, and the temporary layer can therefore be removed selectively.

The advantage of the present invention is mainly that the packaged LED is compact in size. On the other hand, in the flip-chip packaging, the p-contact and n-contact are contacted with the metal bumping pads, the contact area with metal is large thus the thermal dissipations effect is better. If the transparent materials are used for current distributing layer and passivation layer, the metal bumping pads and the following flip-chip packaged substrate can provides the reflection effect of the light of LED. The light emitting area of the flip-chip package is toward the transparent substrate of the LED, and there is no p-contact and n-contact covering the light therefore the light emitting area is larger, which can more efficiently using the light emitting area. In addition, the present invention does not need transparent conductive layer for contact conductor layer of current distribution, and does not need transparent passivation layer for protection, therefore the selection of material can be more flexible.

Although specific embodiments have been illustrated and described, it will be obvious to those skilled in the art that various modifications may be made without departing from what is intended to be limited solely by the appended claims.

What is claimed is:

1. A method for packaging LED, comprising:
providing a LED structure;
forming a conduction enhancing layer on said LED structure, and electrically connected to p-contact and n-contact of said LED structure;
forming a bumping area definition layer on said conduction enhancing layer, wherein said bumping area definition layer includes two electrode areas;
forming two bumping pads on said two electrode areas, and electrically connected to said conduction enhancing layer;
removing said bumping area definition layer; and
removing selectively said exposed conduction enhancing layer for electrically isolating between said two bumping pads.

2. The method in claim 1, wherein said forming said two bumping pads includes plating.

3. The method in claim 1, wherein said forming said two bumping pads includes printing.

4. The method in claim 1, wherein said bumping pads includes gold, silver, copper, nickel gold, solder bump, gold bump, silver bump, copper bump, silver epoxy or solder paste.

5. The method in claim 1, wherein said removing said exposed conductive enhancing layer includes etching.

6. The method in claim 1, further comprising forming a temporary layer on said LED structure and overlapping with said bumping area definition layer prior to said forming said conductive enhancing layer.

7. The method in claim 6, wherein said temporary layer includes highly selective ratio layer.

8. The method in claim 7, wherein said removing said conductive enhancing layer includes peeling method.

9. The method in claim 1, wherein said LED structure is formed on a transparent substrate.

10. The method in claim 1, further comprising a passivation layer formed on said LED structure.

11. A method for packaging LED, comprising:
providing a LED structure;
forming a passivation layer on said LED structure and exposing p contact and n-contact of said LED structure;
forming a bumping area definition layer on said conduction enhancing layer and overlapping with said high selective ration layer;
forming two bumping pads on said two bumping area;
removing said bumping area definition layer; and
selectively removing said exposed conduction enhancing layer by peeling method.

12. The method in claim 11, wherein said forming two bumping pads including plating.

13. The method in claim 11, wherein said forming said two bumping pads includes printing.

14. The method in claim 11, wherein said bumping pads includes gold, silver, copper, nickel gold, solder bump, gold bump, silver bump, copper bump, silver epoxy or solder paste.

15. The method in claim 11, wherein said LED structure is formed on a transparent substrate.

16. The method in claim 11, wherein said temporary layer includes highly selective ratio layer.

17. A LED structure for flip-chip package, comprising:
a substrate;
a LED structure formed on said substrate, and a p-type conductive semiconductor layer formed on said n-type conductive semiconductor layer;
a p-contact formed on said p-type conductive semiconductor layer;
a n-contact formed on said n-type conductive semiconductor layer;
a passivation layer formed on said p-type conductive layer and exposed p-contact ad n-contact;
a conduction enhancing layer resided on said p-contact and said n-contact, and electrically connected to said p-contact and said n-contact; and
two bumping pads formed on said conduction enhancing layer and electrically connected to said p-contact and said n-contact separately.

18. The structure in claim 17, wherein said two bumping pads includes gold, silver, copper, nickel gold, solder bump, gold bump, silver bump, copper bump, silver epoxy or solder paste.

19. The structure in claim 17, wherein said substrate includes transparent material.
